(19) United States
(12) Patent Application Publication
(10) Pub. No.: US 2015/0221352 A1
(43) Pub. Date: Aug. 6, 2015

(54) SEMICONDUCTOR DEVICES INCLUDING E-FUSE ARRAYS

(71) Applicant: SK hynix Inc., Icheon-si Gyeonggi-do (KR)

(72) Inventor: Ig Soo KWON, San Ramon, CA (US)

(73) Assignee: SK hynix Inc., Icheon-si Gyeonggi-do (KR)

(21) Appl. No.: 14/174,653

(22) Filed: Feb. 6, 2014

(51) Int. Cl. G11C 7/20; G06F 1/26

(52) U.S. Cl. CPC G11C 7/20; G06F 1/26

(57) ABSTRACT

Semiconductor devices are provided. The semiconductor device includes a voltage generation control circuit, a read voltage generator, and a control data storage unit. The voltage generation control circuit generates a voltage control signal enabled during a boot-up operation and disabled after the boot-up operation. The read voltage generator generates a read voltage signal in response to a read signal and the voltage control signal. The control data storage unit executes the boot-up operation in response to the read voltage signal, a row address signal and a column address signal to transmit control data to a first data latch unit and a second data latch unit.

### BACKGROUND

1. Technical Field

Embodiments of the present disclosure relate to semiconductor devices.

2. Related Art

Semiconductor devices may include fuses that store information necessary for various internal control operations, for example, setup information, repair information or the like. General fuses can be programmed in a wafer level because a logic level of each data is determined according to an electrical open/short state of each fuse. However, once the semiconductor devices are encapsulated to form semiconductor packages, it may be impossible to program the general fuses in the semiconductor packages. E-fuses are widely used to solve the aforementioned disadvantage. Each of the e-fuses may be realized using a transistor, for example, a nonvolatile memory (NVM) cell transistor having a floating gate or a charge trapping layer. In such a case, a data may be stored in the e-fuse by programming or erasing the transistor to change a threshold voltage of the transistor. That is, the e-fuse may be electrically open or short according to a resistance value between a source and a drain of the transistor employed as the e-fuse.

In order to correctly recognize the data stored in the e-fuses, a size of the transistors employed as the e-fuses has to be increased or amplifiers have to be used without increasing the size of the transistors employed as the e-fuses. However, in any case, there may be limitations in increasing the integration density of the semiconductor devices including the e-fuses.

Recently, e-fuse arrays have been proposed to solve the limitations of the integration density and to store the information necessary for various internal control operations. In the event that the e-fuse arrays are employed in the semiconductor devices, the e-fuse arrays may share the amplifiers with each other. Accordingly, the integration density of the semiconductor devices may be improved.

### SUMMARY

Various embodiments are directed to semiconductor devices.

According to various embodiments, a semiconductor device includes a voltage generation control circuit, a read voltage generator and a control data storage unit. The voltage generation control circuit generates a voltage control signal enabled during a boot-up operation and disabled after the boot-up operation. The read voltage generator generates a read voltage signal in response to a read signal and the voltage control signal. The control data storage unit executes the boot-up operation in response to the read voltage signal, a row address signal and a column address signal to transmit control data to a first data latch unit and a second data latch unit.

According to various embodiments, a semiconductor device includes a read signal generator, a read voltage generator, a control data storage unit, a verification unit and a voltage generation control circuit. The read signal generator generates a read signal for a boot-up operation. The read voltage generator generates a read voltage signal in response to the read signal and a voltage control signal. The control data storage unit executes the boot-up operation in response to the read voltage signal, a row address signal and a column address signal to transmit control data to a first data latch unit and a second data latch unit. The verification unit generates a complete signal enabled when the control data are normally transmitted to the first and second data latch units. The voltage generation control circuit generates the voltage control signal in response to the start signal and the complete signal to control generation of the read voltage signal.

In an embodiment, a system comprises: a processor; a controller suitable for receiving a request and a data from the processor; and a memory unit suitable for receiving the request and the data from the controller, wherein the memory unit includes: a voltage generation control circuit suitable for generating a voltage control signal enabled during a boot-up operation and disabled after the boot-up operation; a read voltage generator suitable for generating a read voltage signal in response to a read signal and the voltage control signal; and a control data storage unit suitable for executing the boot-up operation in response to the read voltage signal, a row address signal and a column address signal to transmit control data to a first data latch unit and a second data latch unit.

### BRIEF DESCRIPTION OF THE DRAWINGS

Embodiments of the present invention will become more apparent in view of the attached drawings and accompanying detailed description, in which:

FIG. 1 is a block diagram illustrating a semiconductor device according to an embodiment of the present invention;

FIG. 2 is a block diagram illustrating a voltage generation control circuit included in the semiconductor device of FIG. 1; and

FIG. 3 is a logic circuit diagram illustrating a voltage control signal generator included in the voltage generation control circuit of FIG. 2.

FIG. 4 illustrates a block diagram of a system employing a memory controller circuit in accordance with an embodiment of the present invention.

### DETAILED DESCRIPTION

Embodiments of the present invention will be described hereinafter with reference to the accompanying drawings. However, the embodiments described herein are for illustrative purposes only and are not intended to limit the scope of the invention.

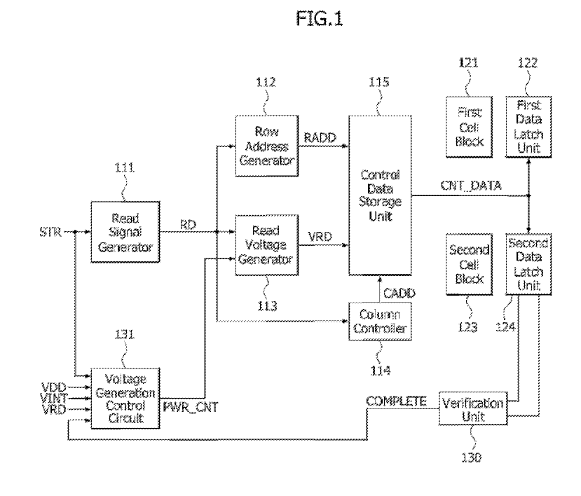

Referring to FIG. 1, a semiconductor device according to an embodiment may include a read signal generator 111, a row address generator 112, a read voltage generator 113, a column controller 114, a control data storage unit 115, a first cell block 121, a first data latch unit 122, a second cell block 123, a second data latch unit 124, a verification unit 130 and a voltage generation control circuit 131.

The read signal generator 111 may generate a read signal RD enabled when a start signal STR enabled for a boot-up operation is inputted thereto. A moment that the start signal STR is enabled may be set to be different according to the embodiments. Logic levels of the start signal STR and the read signal RD which are enabled may also be set to be different according to the embodiments.

The row address generator 112 may generate a row address signal RADD in synchronization with the read signal RD and may apply the row address signal RADD to the control data storage unit 115. The read voltage generator 113 may generate a read voltage signal VRD in response to the read signal RD and a voltage control signal PWR_CNT and may apply the read voltage signal VRD to the control data storage unit 115. The column controller 114 may generate a column address signal CADD in synchronization with the read signal RD and may apply the column address signal CADD to the control data storage unit 115.

The control data storage unit 115 may transmit data stored in an e-fuse array including memory cells (not shown) coupled to a row line (not shown) selected by the row address signal RADD to column lines (not shown) in response to the read voltage signal VRD; and may amplify the data on column lines selected by the column address signal CADD to output the amplified data as the control data CNT_DATA. The control data CNT_DATA may include information for controlling internal operations of the first cell block 121 and information for controlling internal operations of the second cell block 123. The information for controlling the internal operations of the first and second cell blocks 121 and 123 may be repair information or set-up information used in repair operations that replace failed cells in the first and second cell blocks 121 and 123 with redundancy cells. The information included in the control data CNT_DATA to control the internal operations of the first cell block 121 may be transmitted to the first data latch unit 122 to be latched; and the information included in the control data CNT_DATA to control the internal operations of the second cell block 123 may be transmitted to the second data latch unit 124 to be latched. The control data storage unit 115 may be suitable for executing the boot-up operation in response to the read voltage signal VRD, row address signal RADD, and the column address signal CADD.

The verification unit 130 may generate a complete signal COMPLETE enabled when the boot-up operation is normally executed. That is, the verification unit 130 may generate the complete signal COMPLETE enabled when the information included in the control data CNT_DATA to control the internal operations of the first cell block 121 is transmitted to the first data latch unit 122 to be latched; and the information included in the control data CNT_DATA to control the internal operations of the second cell block 123 is transmitted to the second data latch unit 124 to be latched.

The voltage generation control circuit 131 may detect levels of an external voltage signal VDD, an internal voltage signal VINT and the read voltage signal VRD; and may receive the start signal STR and the complete signal COMPLETE to generate the voltage control signal PWR_CNT for controlling an operation of the read voltage generator 113 that generates the read voltage signal VRD. The voltage generation control circuit 131 may be suitable for generating the voltage control signal PWR_CNT enabled during the boot-up operation and disabled after the boot-up operation.

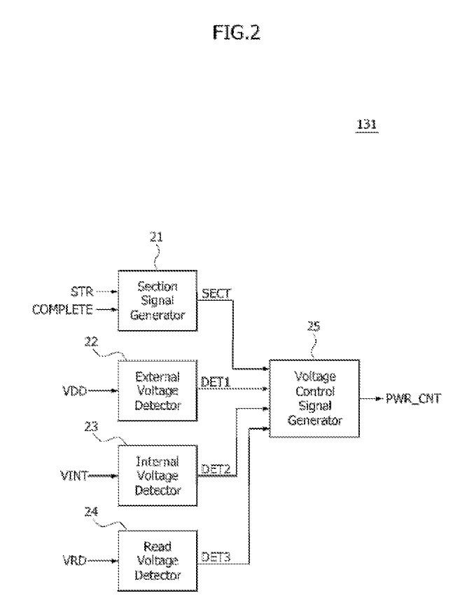

Referring to FIG. 2, the voltage generation control circuit 131 may include a section signal generator 21, an external voltage detector 22, an internal voltage detector 23, a read voltage detector 24 and a voltage control signal generator 25.

The section signal generator 21 may generate a section signal SECT which is enabled during a period from a moment that the start signal STR is enabled till a moment that the complete signal COMPLETE is enabled. While the section signal SECT is enabled, the boot-up operation may be executed such that the information included in the control data CNT_DATA to control the internal operations of the first cell block 121 is transmitted to the first data latch unit 122; and is latched and the information included in the control data CNT_DATA to control the internal operations of the second cell block 123 is transmitted to the second data latch unit 124 and is latched.

The external voltage detector 22 may generate a first detection signal DET1 enabled when a level of the external voltage signal VDD is higher than a first target level. The internal voltage detector 23 may generate a second detection signal DET2 enabled when a level of the internal voltage signal VINT is higher than a second target level. The read voltage detector 24 may generate a third detection signal DET3 enabled when a level of the read voltage signal VRD is higher than a third target level. The first to third target levels may be set to have diverse levels according to the embodiments. Logic levels of the first to third detection signals DET1, DET2 and DET3 which are enabled may be set to have diverse levels according to the embodiments. Accordingly, the voltage generation control circuit 131 may output the voltage control signal PWR_CNT generated from the section signal SECT enabled during the boot-up operation when the first to third detection signals DET1, DET2, and DET3 are enabled.

The voltage control signal generator 25 may output the voltage control signal PWR_CNT generated from the section signal SECT while all the first to third detection signals DET1, DET2 and DET3 are enabled. The voltage control signal PWR_CNT may be a signal for controlling an operation of the read voltage generator 113 that generates the read voltage signal VRD.

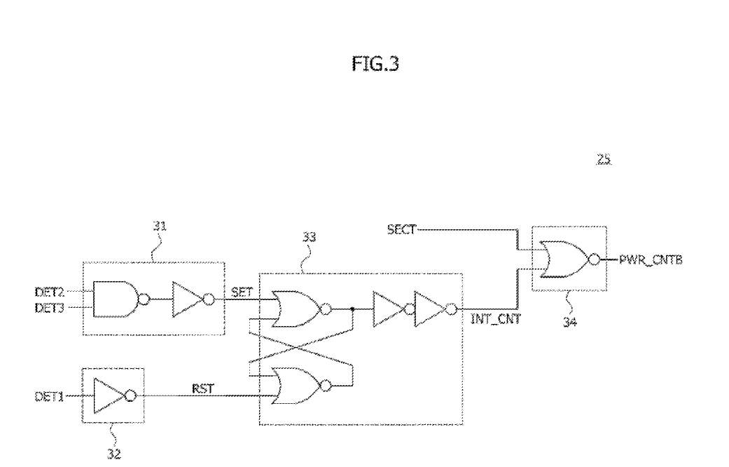

Referring to FIG. 3, the voltage control signal generator 25 may include a set signal generator 31, a reset signal generator 32, an internal control signal generator 33 and a buffer unit 34.

The set signal generator 31 may generate a set signal SET enabled to have a logic “high” level while both the second and third detection signals DET2 and DET3 are enabled. The reset signal generator 32 may generate a reset signal RST disabled to have a logic “low” level when the first detection signal DET1 is enabled. The internal control signal generator 33 may generate an internal control signal INT_CNT enabled to have a logic “low” level when the set signal SET is enabled to have a logic “high” level and the reset signal RST is disabled to have a logic “low” level. The buffer unit 34 may inversely buffer the section signal SECT to generate the voltage control signal PWR_CNT while the internal control signal INT_CNT is enabled to have a logic “low” level to output the buffered section signal SECT as the voltage control signal PWR_CNT. The internal control signal INT_CNT may be enabled while the first, second and third detection signals DET1, DET2, and DET3 are enabled. Accordingly, the voltage control signal generator 25 may be suitable for buffering the section signal SECT in response to the first detection signal DET1, the second detection signal DET2, and the third detection signal DET3 to generate the voltage control signal PWR_CNT.

The semiconductor device according to the aforementioned embodiments may generate the voltage control signal PWR_CNT, which is enabled during the boot-up operation and is disabled after the boot-up operation, to control an operation of the read voltage generator 113 that generates the read voltage signal VRD. More specifically, if the boot-up operation terminates, the read voltage signal VRD applied to the control data storage unit 115 to output the control data CNT_DATA during the boot-up operation may not be generated any more. That is, since the read voltage signal VRD is not generated when the boot-up operation terminates, the power consumption of the semiconductor device can be reduced.

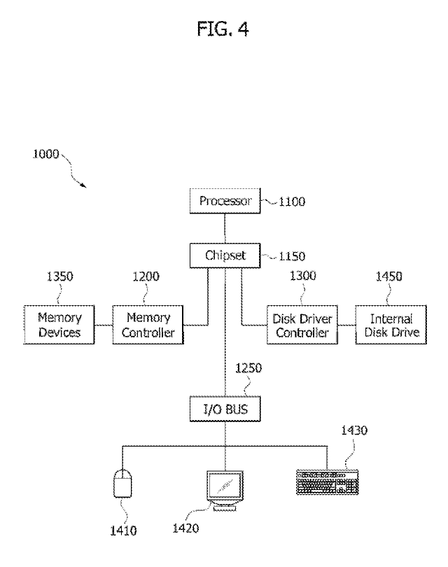

Referring to FIG. 4, a block diagram of a system 1000 employing a memory controller 1200 in accordance with an embodiment of the invention is illustrated. The system 1000 may include one or more processors or central processing units (“CPUs”) 1100. The processor 1100 may be used individually or in combination with other CPUs.

A chipset 1150 may be operably coupled to the processor 1100. The chipset 1150 may be a communication pathway for signals between the processor 1100 and other components of the system 100. The other components may include a memory controller 1200, an input/output (“I/O”) bus 1250, and a disk drive controller 1300. Depending on the configuration of the system, any one of a number of different signals may be transmitted through the chipset 1150.

The memory controller 1200 may be operably coupled to the chipset 1150. The memory controller 1200 may include at least one memory controller which delays the generation of the address signal, and blocks consecutive accesses, of which the number exceeds the predetermined critical value, to the same word line or the same bit line of a selected memory bank of a memory unit. Thus, the memory controller 1200 can receive a request provided from the processor 1100, through the chipset 1150. The memory controller 1200 may be operably coupled to one or more memory devices 1350. The memory devices 1350 may correspond to the semiconductor device described above.

The chipset 1150 may also be coupled to the I/O bus 1250. The I/O bus 1250 may serve as a communication pathway for signals from the chipset 1150 to the I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430.

The disk drive controller 1300 may also be operably coupled to the chipset 1150. The disk drive controller 1300 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

What is claimed is:

1. A semiconductor device comprising:
a voltage generation control circuit suitable for generating a voltage control signal enabled during a boot-up operation and disabled after the boot-up operation;
a read voltage generator suitable for generating a read voltage signal in response to a read signal and the voltage control signal; and
a control data storage unit suitable for executing the boot-up operation in response to the read voltage signal, a row address signal and a column address signal to transmit control data to a first data latch unit and a second data latch unit.

2. The semiconductor device of claim 1, wherein the voltage generation control circuit outputs the voltage control signal generated from a section signal enabled during the boot-up operation when a level of an external voltage signal, a level of an internal voltage signal and a level of the read voltage signal are higher than a first predetermined level, a second predetermined level and a third predetermined level, respectively.

3. The semiconductor device of claim 2,
wherein the voltage generation control circuit includes a voltage control signal generator suitable for buffering the section signal in response to a first detection signal, a second detection signal and a third detection signal to generate the voltage control signal; and
wherein the first detection signal is generated by detecting the external voltage signal, the second detection signal is generated by detecting the internal voltage signal, and the third detection signal is generated by detecting the read voltage signal.

4. The semiconductor device of claim 3,
wherein the first detection signal is enabled when a level of the external voltage signal is higher than a first target level;
wherein the second detection signal is enabled when a level of the internal voltage signal is higher than a second target level; and
wherein the third detection signal is enabled when a level of the read voltage signal is higher than a third target level.

5. The semiconductor device of claim 4,
wherein the voltage control signal generator includes a buffer unit suitable for buffering the section signal in response to an internal control signal to output the buffered section signal as the voltage control signal; and
wherein the internal control signal is enabled while the first, second and third detection signals are enabled.

6. The semiconductor device of claim 3, wherein the voltage generation control circuit further includes:
a section signal generator suitable for generating the section signal in response to a start signal and a complete signal;
an external voltage detector suitable for generating the first detection signal enabled when a level of the external voltage signal is higher than a first target level;
an internal voltage detector suitable for generating the second detection signal enabled when a level of the internal voltage signal is higher than a second target level; and
a read voltage detector suitable for generating the third detection signal enabled when a level of the read voltage signal is higher than a third target level.

7. The semiconductor device of claim 1,
wherein the read voltage generator is suitable for generating the read voltage signal when the read signal is enabled; and
wherein the read voltage generator is suitable for terminating generation of the read voltage signal when the voltage control signal is disabled.

8. The semiconductor device of claim 1, wherein the control data storage unit is suitable for transmitting data stored in memory cells in response to the read voltage signal and is suitable for amplifying the data to output the amplified data as the control data.

9. The semiconductor device of claim 8, wherein the memory cells are part of an e-fuse array in the control data storage unit.

10. A semiconductor device comprising:
a read signal generator suitable for generating a read signal for a boot-up operation;
a read voltage generator suitable for generating a read voltage signal in response to the read signal and a voltage control signal;
a control data storage unit suitable for executing the boot-up operation in response to the read voltage signal, a row address signal and a column address signal to transmit control data to a first data latch unit and a second data latch unit;
a verification unit suitable for generating a complete signal enabled when the control data are normally transmitted to the first and second data latch units; and
a voltage generation control circuit suitable for generating the voltage control signal in response to a start signal and the complete signal to control generation of the read voltage signal.

11. The semiconductor device of claim 10, wherein the control data storage unit is suitable for transmitting data stored in memory cells in response to the read voltage signal and is suitable for amplifying the data to output the amplified data as the control data.

12. The semiconductor device of claim 11, wherein the memory cells are part of an e-fuse array in the control data storage unit.

13. The semiconductor device of claim 10, wherein the voltage generation control circuit outputs the voltage control signal generated from a section signal enabled during the boot-up operation when a level of an external voltage signal, a level of an internal voltage signal and a level of the read voltage signal are higher than a first predetermined level, a second predetermined level and a third predetermined level, respectively.

14. The semiconductor device of claim 13,
wherein the voltage generation control circuit includes a voltage control signal generator suitable for buffering the section signal in response to a first detection signal, a second detection signal and a third section signal to generate the voltage control signal; and
wherein the first detection signal is generated by detecting the external voltage signal, the second detection signal is generated by detecting the internal voltage signal, and the third detection signal is generated by detecting the read voltage signal.

15. The semiconductor device of claim 14,
wherein the first detection signal is enabled when a level of the external voltage signal is higher than a first target level;
wherein the second detection signal is enabled when a level of the internal voltage signal is higher than a second target level; and
wherein the third detection signal is enabled when a level of the read voltage signal is higher than a third target level.

16. The semiconductor device of claim 15,
wherein the voltage control signal generator includes a buffer unit suitable for buffering the section signal in response to an internal control signal to output the buffered section signal as the voltage control signal; and
wherein the internal control signal is enabled while the first, second and third detection signals are enabled.

17. The semiconductor device of claim 14, wherein the voltage generation control circuit further includes:
a section signal generator suitable for generating the section signal in response to the start signal and the complete signal;
an external voltage detector suitable for generating the first detection signal enabled when a level of the external voltage signal is higher than a first target level;
an internal voltage detector suitable for generating the second detection signal enabled when a level of the internal voltage signal is higher than a second target level; and
a read voltage detector suitable for generating the third detection signal enabled when a level of the read voltage signal is higher than a third target level.

18. The semiconductor device of claim 10,
wherein the read voltage generator is suitable for generating the read voltage signal when the read signal is enabled; and
wherein the read voltage generator is suitable for terminating generation of the read voltage signal when the voltage control signal is disabled.

19. The semiconductor device of claim 10,
wherein the voltage control signal is terminated after the boot-up operation to control an operation of the read voltage generator.

20. A system comprising:
a processor;
a controller suitable for receiving a request and a data from the processor; and
a memory unit suitable for receiving the request and the data from the controller,
wherein the memory unit comprises:
a voltage generation control circuit suitable for generating a voltage control signal enabled during a boot-up operation and disabled after the boot-up operation;
a read voltage generator suitable for generating a read voltage signal in response to a read signal and the voltage control signal; and
a control data storage unit suitable for executing the boot-up operation in response to the read voltage signal, a row address signal and a column address signal to transmit control data to a first data latch unit and a second data latch unit.
